(19) United States
(12) Patent Application Publication
(10) Pub. No.: US 2014/0312495 A1
(43) Pub. Date: Oct. 23, 2014

(54) FAN OUT INTEGRATED CIRCUIT DEVICE PACKAGES ON LARGE PANELS

(71) Applicant: LSI Corporation, Milpitas, CA (US)

(72) Inventor: John Osenbach, Kutztown, PA (US)

(21) Appl. No.: 13/936,350

(22) Filed: Jul. 8, 2013

Related U.S. Application Data
(60) Provisional application No. 61/814,990, filed on Apr. 23, 2013.

(51) Int. Cl. H01L 23/31; H01L 21/56

(52) U.S. Cl. CPC H01L 23/3128; H01L 21/565
USPC 257/738; 438/107

(57) ABSTRACT

A method of manufacturing an integrated circuit package. The method comprises providing a carrier substrate having a planar surface. The method comprises placing a plurality of semiconductor device dies active-side down at laterally spaced-apart locations on the planar surface. The method comprises covering the semiconductor device dies with a mold compound to define laterally spaced-apart mold sub-arrays on the planar surface. The method comprises curing the laterally spaced-apart mold sub-arrays, wherein the semiconductor device dies are retained at substantially the same laterally spaced-apart locations on the planar surface after the curing.

### CROSS-REFERENCE TO RELATED APPLICATION

This application claims the benefit of U.S. Provisional Application Ser. No. 61/814,990, filed by John Osenbach on Apr. 23,2013, entitled “FAN OUT INTEGRATED CIRCUIT DEVICE PACKAGES ON LARGE PANELS,” commonly assigned with this application and incorporated herein by reference.

### BACKGROUND

Wafer level integrated circuit (IC) device packages, such as embedded wafer level packages, are attractive because of the decreased overall production costs. The desire to further reduce costs and to fabricate more complex device packages is driving the use of ever-larger wafer sizes. It has been found, however, as the wafer size is increased, the percentage yield of functional IC device packages per wafer can decrease.

### SUMMARY

The present invention is manifest, in one embodiment, a method of manufacturing an integrated circuit package. The method comprises providing a carrier substrate having a planar surface. The method comprises placing a plurality of semiconductor device dies active-side down at laterally spaced-apart locations on the planar surface. The method comprises covering the semiconductor device dies with a mold compound to define laterally spaced-apart mold sub-arrays on the planar surface. The comprises curing the laterally spaced-apart mold sub-arrays, wherein the semiconductor device dies are retained at substantially the same laterally spaced-apart locations on the planar surface after the curing.

Embodiments of the invention manifest in other forms include but are not limited to an integrated circuit package. The integrated circuit package comprises a plurality of semiconductor device dies embedded in one of a plurality of laterally spaced-apart mold sub-arrays. An active side of the dies are not covered by the spaced-apart mold sub-arrays and the active side the dies are substantially in a same plane as one side of the spaced-apart mold sub-arrays.

### BRIEF DESCRIPTION

Other embodiments of the invention will become apparent from the following descriptions taken in conjunction with the accompanying drawings, in which:

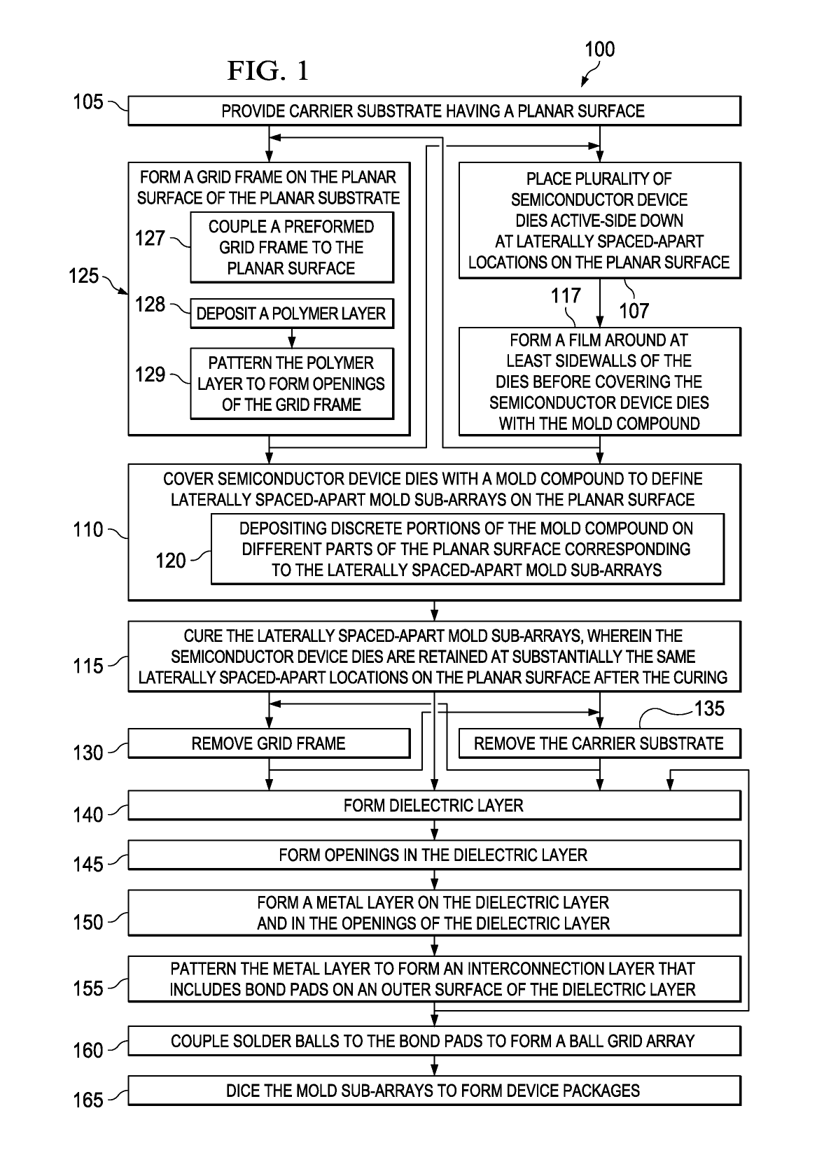

FIG. 1 presents a flow diagram illustrating selective steps in an embodiment of the invention manifest as a method of manufacturing an integrated circuit package of the disclosure;

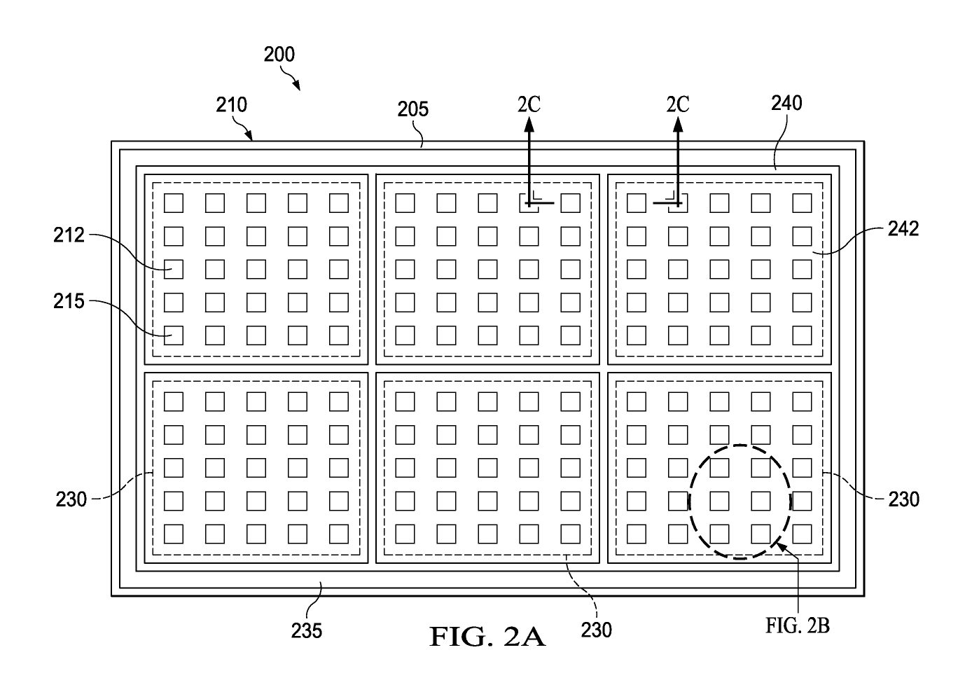

FIG. 2A presents a plan view of an embodiment of the invention manifest as an integrated circuit device package of the disclosure such as a device package at a stage of one embodiment of the method discussed in the context of FIG. 1;

FIG. 2B presents a detail plan view of a portion of the device package depicted in FIG. 2A;

FIG. 2C presents a detail cross-sectional view of a portion of the device package depicted in FIG. 2B;

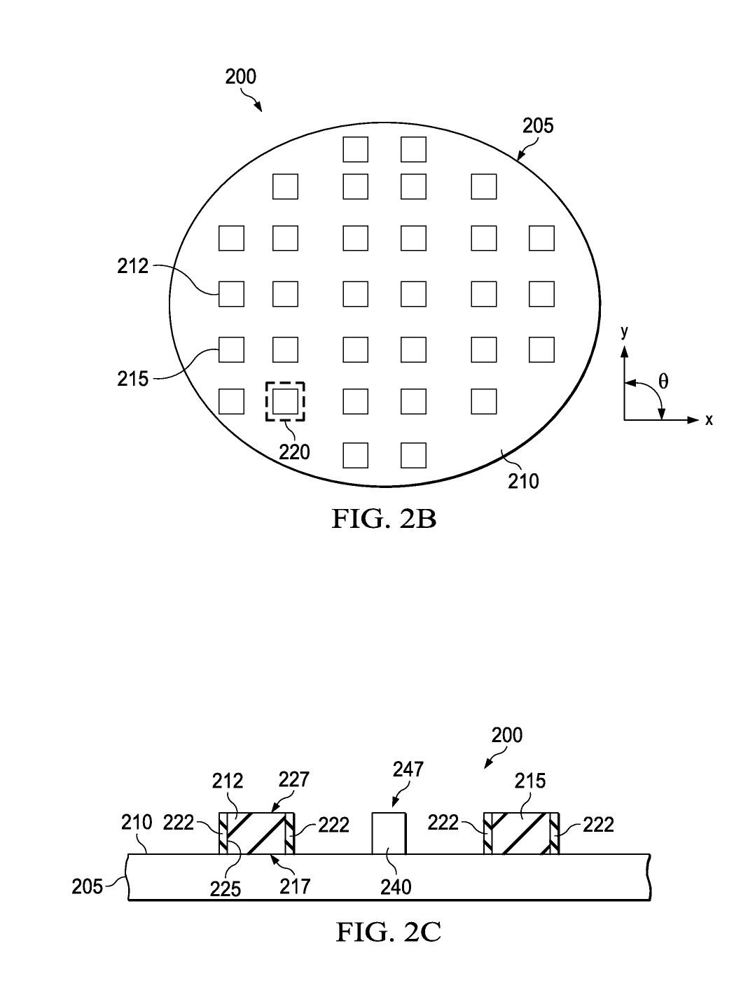

FIGS. 3A, 3B and 3C present plan and cross-sectional views of an embodiment of the invention manifest as a device package analogous to the view presented in FIGS. 2A, 2B and 2C, respectively, after a further stage in an embodiment of method discussed in the context of FIG. 1;

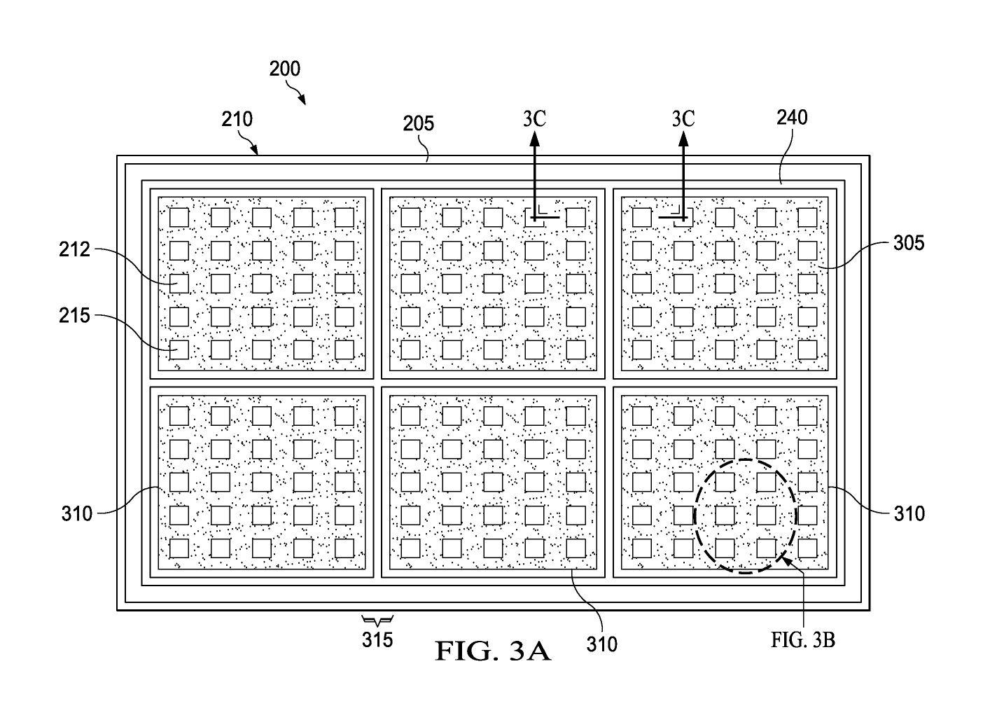

FIG. 4 presents a cross-sectional view of an embodiment of the invention manifest as a device package analogous to the view depicted in FIG. 3C, after a further stage in an embodiment of method discussed in the context of FIG. 1;

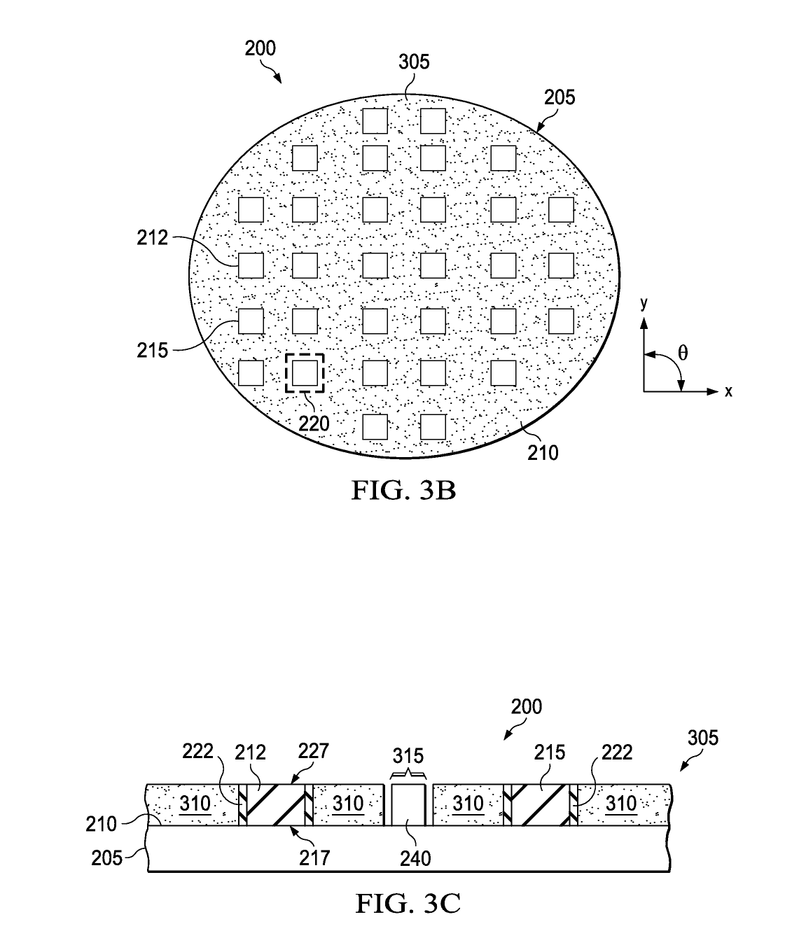

FIG. 5 presents a cross-sectional view of an embodiment of the invention manifest as another device package analogous to the view depicted in FIG. 3C, after a further stage in an embodiment of method discussed in the context of FIG. 1; and

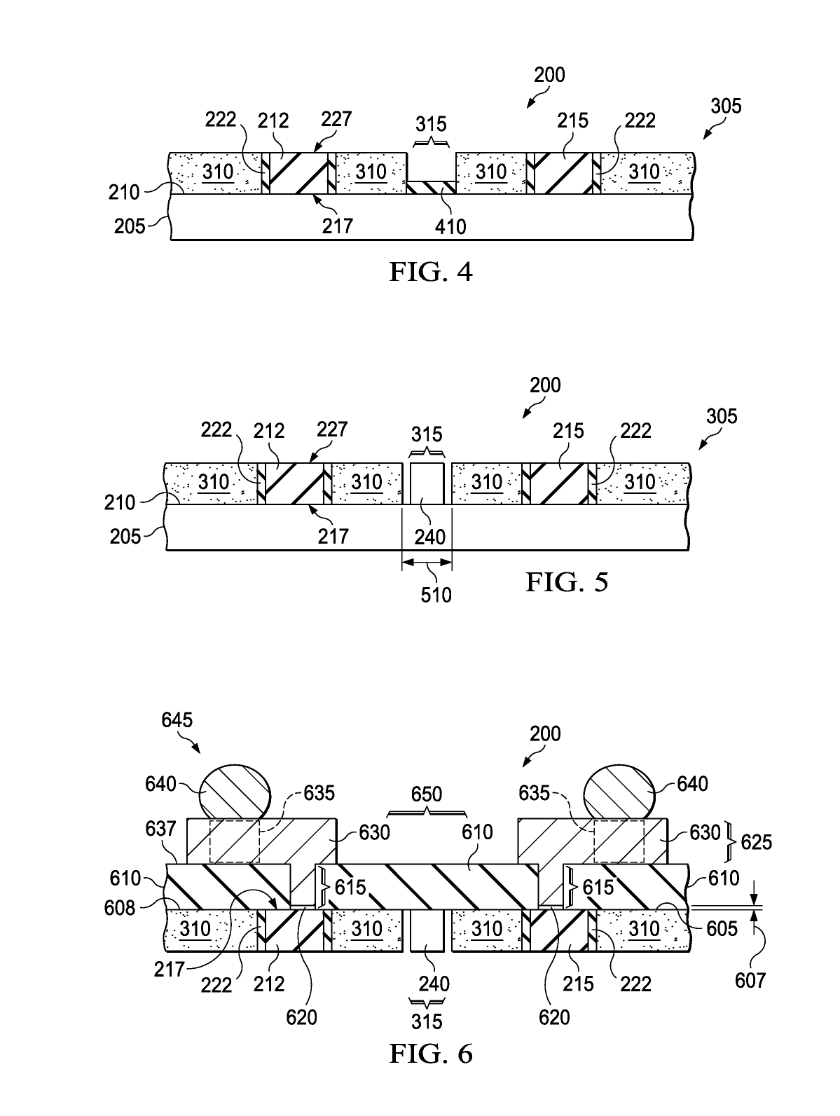

FIG. 6 presents a cross-sectional view of embodiment of the invention manifest as another device package analogous to the view depicted in FIG. 5, after further stages in an embodiment of the method discussed in the context of FIG. 1.

### DETAILED DESCRIPTION

The present disclosure benefits from the realization that decreased yield percentages of device packages per wafer or carrier substrate can occur because the mold covering the integrated circuit dies can cause undesirable movement of the dies when the mold is cured. The undesirable movement is thought to be influenced by the shrinkage of the mold as the mold cures and solidifies and/or by the differences in the coefficient of thermal expansion and the mold compound. Moreover, die movement can be exacerbated for those dies located in the perimeter regions of the wafer if during curing, the mold laterally shrinks from the perimeter of the mold toward the center of the mold. Lateral or rotational movement of the IC dies, in turn, can cause lithographic misalignment during subsequent processing steps used to form electrical interconnections with the dies, thereby leading to reduced yields. The relative effects of such die movement also increase as wafer size is increased since the largest portion area of wafer is in the perimeter region.

It is further recognized as part of the present disclosure that these yield losses could be mitigated by limiting the cross-sectional area of the mold to a size where device yields are acceptably higher (e.g., about 99.5% or higher yields in some embodiments). It is also recognized that the cost benefits associated with scaling up large wafer sizes for package fabrication can still be substantially realized by forming a plurality of laterally spaced-apart mold sub-arrays on the wafer surface. Spacing apart the mold sub-arrays mitigates the mechanical stresses of shrinkage and/or CTE from extending beyond the individual mold sub-arrays and thereby reduces excessive die movement.

One embodiment of the invention can be manifest as a method of manufacturing an IC package. FIG. 1 presents a flow diagram illustrating selective steps in an embodiment of the invention manifest as a method 100 of manufacturing an IC package of the disclosure, such as any of the IC packages 200, including intermediate packages, such as illustrated in FIGS. 2A-6.

With continuing reference to FIG. 1, FIG. 2A presents a plan view of an embodiment of the invention manifest as an integrated circuit device package 200 of the disclosure such as a device package at a stage of one embodiment of the method discussed in the context of FIG. 1. FIG. 2B presents a detail plan view of a portion of the device package 200 depicted in FIG. 2A, and, FIG. 2C presents a detail cross-sectional view of a portion of the device package 200 depicted in FIG. 2B.

The method 100 comprises a step 105 of providing a carrier substrate 205 having a planar surface 210. The method 100 comprises a step 107 of placing a plurality of semiconductor device dies 212, 215, active-side 217 (FIG. 2C) down, at laterally spaced-apart locations 220 (FIG. 2B) on the planar surface 210. The dies 212, 215 are spaced-apart to provide space for forming fan-out interconnection routings on the package 100, such as further described below.

The carrier substrate 205 can be or include any conventional carrier tape used in IC package manufacturing. Although the carrier substrate 205 in FIG. 2A is depicted as a being a rectangular shaped carrier panel, in other embodiments, the carrier substrate 205 can be a circularly-shaper carrier wafer or square-shaped carrier panel. In some embodiments, the carrier substrate 205 can be composed of or include a flexible polymer layer such as a polyvinyl chloride layer and an adhesive layer such as a synthetic acrylic adhesive bonded to the one surface 210 of the substrate 205 that the dies 212, 215 are located on. As a non-limiting example, in some embodiments the carrier substrate 205 can be composed of epak Part No. 18733 (Epak Electronics Ltd., United Kingdom).

In some embodiments, the semiconductor device dies 212, 215 can all be of a same types of dies, while in other embodiments, the dies 212, 215 can be of different types. For instance, with limitation, some dies 212 placed on the substrate 205 can be configured as analog device and other dies 215 on the substrate 205 can be configured as logic devices. In still other embodiments the dies 212 and 215 can be configured as memory, I/O, radio-frequency devices or combinations thereof. The active side 217 of each die 215 is placed active side 217 (FIG. 2C) face-down in the substrate 205 to protect the bond pads, transistors and other active or passive device components on the active side 217 during substrate handling, mold deposition and curing.

FIGS. 3A, 3B and 3C present plan and cross-sectional views of embodiment of the invention manifest as a device package 200 analogous to the view presented in FIGS. 2A, 2B and 2C, respectively, after a further stage in an embodiment of method 100 discussed in the context of FIG. 1.

The method 100 further comprises a step 110 of covering the semiconductor device dies 215 with a mold compound 305 to define laterally spaced-apart mold sub-arrays 310 on the planar surface 210. The method 100 further comprises a step 115 of curing the laterally spaced-apart mold sub-arrays 310, wherein the semiconductor device dies 215 are retained at substantially the same laterally spaced-apart locations 220 on the planar surface after the curing step 115.

One skilled in the pertinent arts would be familiar with type of materials used as the mold compound 305. In some embodiments, for example, the mold compound 305 can be or include an epoxy compound such as Nagase R4212 (Nagase America Corp. N.Y.). One skilled in the pertinent arts would be familiar with such curing processes, including heating, ultraviolet and infrared light curing.

To be retained at substantially the same laterally spaced-apart locations 220 after the covering and curing steps 110, 115 it is desirable for the device dies 212, 215 to not have any substantial lateral or rotational movement in a plane (e.g., an x-y plane as depicted in FIG. 3B) of the dies 212, 215 that is parallel to the planar surface 210 as compared to before these steps 110, 115 (e.g., the locations depicted in FIGS. 2A-2c). For instance, in some embodiments, the lateral movement of any one of the semiconductor device dies in the x or y direction after curing (step 115) is about 1 micron or less, and in some embodiments, about 0.1 microns or less and in some embodiments about 0.01 microns or less. For instance, in some embodiments, the rotational movement (e.g., angle θ as depicted in FIG. 3B) of any one of the semiconductor device dies 212, 215 after curing (step 115) is about 5 degrees or less, and in some embodiments, about 1 degree or less, and in some embodiments, about 0.5 degrees microns or less.

In some embodiments of the invention manifest as a method 100, further includes a step 117 of forming a film 222 (FIG. 2C) on at least sidewalls 225 around the dies 212, 215, before covering the dies 212, 215 with the mold compound in step 110. In some embodiments the film 222 can conformally cover both the side walls 225 and bottoms 227 of the dies 212, 215, e.g., while still leaving an empty space between adjacent dies. The film 222 can help anchor the die 212, 215 at the designated locations 220 to reduce movement of die 212, 215, e.g., during covering the dies 212, 215 with the mold compound 305 or during subsequent processing steps, and thereby improve device yields. Without limitation, in some embodiments, the film 222 can be composed of an epoxy such as a B-stage epoxy and could be at least partial cured, e.g., via infrared light curing, and then fully cured as part of the mold curing step 115.

In some embodiments of the invention manifest as a method 100 the covering step 110 includes a step 120 of depositing discrete portions of the mold compound 305 on different parts of the planar surface 210 that correspond to the laterally spaced-apart mold sub-arrays 310. For instance, discrete portions of the mold compound 305 can be separately deposited by spraying, stamping or similar deposition procedures familiar to those skilled in the pertinent art.

In some embodiments of the invention manifest as a method 100, the step 107 of placing semiconductor device dies 212, 215 includes grouping the dies 212, 215 into regions 230 on the planar surface 210 (FIG. 2A). The regions 230 on the planar surface 210 are separated by die-free zones 235 (FIG. 2A) situated so as to correspond to locations of gaps 315 (FIG. 3A) between the laterally spaced-apart mold sub-arrays 310.

In some embodiments of the invention manifest as a method 100, before the covering step 110, the method 100 further includes a step 125 of forming a grid frame 240 (FIG. 2A) on the planar surface 210 of the planar substrate 205. The grid frame 240 has a plurality of openings 242. Each of the openings 242 of the grid frame 240 define locations for one of the laterally spaced-apart mold sub-arrays 310. For instance, during the covering step 110, the mold compound 305 can be poured, injected or otherwise placed into the openings 242 to form the mold sub-arrays 310.

In some embodiments of the invention manifest as a method 100 or a package 200, the grid frame 240 is composed of a compliant material that resists the translation of mechanical forces from one mold sub-array 310 to adjacent mold sub-arrays 310. In some embodiments, for example, the grid frame material has a low elastic modulus and a long strain. In some embodiments, for example the grid frame material is composed of an elastomeric material such as silicone or similar elastomeric rubbers.

In some embodiments of the invention manifest as a method 100, as part of step 125, a preformed grid frame 240 is coupled to the planar surface 210 in step 127. For example, the preformed grid frame 240 can be formed as a mesh by an injection molding process familiar to those skilled in the pertinent arts. In some embodiments, the preformed grid frame 240 can be coupled in step 127 to the planar surface 210 where the walls 245 (FIG. 2C) of the grid frame 240 are located at the die free zone 235 locations on the planar surface 210. For example, in some embodiments, the preformed grid frame 240 can be adhered to an adhesive on the planar surface 210 of the carrier substrate 205. For example, in some embodiment, the preformed grid frame 240 can be thermo-compressively coupled to the carrier substrate 205.

In some embodiments of the invention manifest as a method 100, as part of step 125, the grid frame 240 is formed by depositing a polymer layer e.g., an elastomeric polymer layer) on the planar surface 210, in step 128, and then the polymer layer is patterned, in step 129, to form the openings 242 of the grid frame 240. For instance, in some embodiments, the grid frame walls 245, defined by the patterning step 129, are located at the die-free zones 325 on the surface 210.

In some embodiments of the invention manifest as a method 100, the grid frame 240 is formed in step 125 before placing the dies 212, 215 on the planar surface 210 (step 107), while in other embodiments the grid frame 240 is formed after the dies 212, 215 have been placed on the planar surface 210. For instance, in some embodiments, it is desirable for the grid frame 240 to be formed (step 125) before placement of dies 212, 215 (step 107) and/or film 222 (step 117) so that the dies 212, 215 and/or film 222 are not subjected to the thermo-compressive forces or temperature associated with coupling the preformed grid frame 240 to the surface 210 in step 127. For instance, in some embodiments, it is desirable for the grid frame 240 to be formed (step 125) before placement of dies (step 107) and/or film 222 (step 117) so that the dies 212, 215 and/or film 222 are not exposed to the step 129 of patterning the polymer layer of grid frame material to form the grid frame 240 on the surface 210.

FIG. 4 presents a cross-sectional view of embodiment of the invention manifest as another the device package 200 analogous to the view depicted in FIG. 3C, after a further stage in an embodiment of method 100 discussed in the context of FIG. 1.

In some embodiments of the invention manifest as a method 100, as illustrated in FIG. 4, the grid frame 240 formed in step 125 is removed in step 130 after curing of the laterally spaced-apart mold sub-arrays (step 115). For example, in some embodiments, a mold tool (e.g., a robotically controlled arm holding the frame) can place the grid frame 240 on or over the planar surface 210 and then after the covering and curing steps 110, 115 the mold tool lifts the grid frame 240 away from of the surface 210. In such embodiments, the gap 315 between adjacent ones of the laterally spaced-apart mold sub-arrays 310 can be an empty (e.g., air filled) space. In some such embodiments, the removed grid frame 240 can then be reused in the fabrication of another device package 200.

FIG. 5 presents a cross-sectional view of embodiment of the invention manifest as another device package 200 analogous to the view depicted in FIG. 3C, after a further stage in an embodiment of method 100 discussed in the context of FIG. 1.

In some embodiments of the invention manifest as a method 100, as illustrated in FIG. 5, the grid frame 240 is retained after the curing of the laterally spaced-apart mold sub-arrays 310 (step 115). In some such embodiments of the package 200, the gap 315 between adjacent ones of the laterally spaced-apart mold sub-arrays 310 can be substantially occupied by the material of the grid frame 240. In some such embodiments, the retained grid frame 240 can help to maintain the planarity of the mold sub-arrays 310 and thereby help keep the active sides 217 of the dies 215 in a same plane to facilitate the precise placement of fan-out interconnection routing on the package 100 in subsequent processing steps.

For some embodiments of the invention manifest as a method 100 or a package 200, adjacent ones of the mold sub-arrays 315 have a separation distance 510 (e.g., FIG. 5) that is a value in a range from about 2 microns to about 100 mm.

In some embodiments of the invention manifest as the method 100 or package 200, the adjacent ones of the laterally spaced-apart mold sub-arrays 310 are fully, separated from each other with no mold compound in the gap 315 between the mold sub-arrays 310. When the mold sub-arrays 310 are fully separated from each other the gap 315 can be very small, since substantially no mechanical forces, e.g., associated with mold shrinkage or CTE mismatch, can be transferred from one mold sub-array 310 to another mold sub-array 310. For example, in some such embodiments, the separation distance 510 can be in the range of about 2 microns to about 100 microns or in some embodiments, the range of about 2 to about 10 microns. Having such a small separation distance 510 facilitates efficient use of the surface 210 for fabricating large numbers of device package 200 per carrier substrate 205.

In other embodiments of the invention manifest as the method 100 or package 200, such as when the adjacent ones of the laterally spaced-apart mold sub-arrays 310 are not fully separated from each other, it can be advantageous to have a larger separation distance 510. For example in some embodiments, the separation distance 510 can be in a range of about 100 microns to about 10000 microns and in some embodiments, a range of about 100 to about 1000 microns. Having such a separation distances 510 can still facilitate efficient use of the surface 210 for package 200 fabrication while at the same time reducing the amount of mechanical forces transferred between the mold sub-arrays 310 during the covering and curing steps 110, 115.

In other embodiments of the invention manifest as the method 100 or package 200, even larger separation distance 510 may be desirable such as when the covering step 112 includes depositing discrete portions of the mold compound 305 depositing discrete portions of the mold compound 305 on different parts of the planar surface 210 (step 117) with no grid frame 240 in place over the surface 210. For example in some embodiments, the separation distance 510 can be in a range of about 10 mm to about 100 mm. Having such larger separation distances 510 can still facilitate efficient use of the surface 210 for package 200 fabrication, while at the same time reduce the extent to which discretely deposited portions of the mold compound 305 contact and run into each other prior to curing (step 115).

As also illustrated in FIG. 5, for some embodiments of the invention manifest as a method 100 or a package 200, gaps 315 between adjacent ones of the laterally separated mold sub-arrays 310 are free of the mold compound 305. However as illustrated in FIG. 4, for other embodiments of the invention manifest as a method 100 or a package 200, there can still be mold compound 305 (e.g., layer 410) present in the gaps 315 between adjacent ones of the laterally separated mold sub-arrays 310. For example, in some embodiments the gap 315 is filled with up to about 50 percent of the mold compound 305, and in some embodiments, up to 25 percent, and in some embodiments up to 10 percent of the mold compound.

In some embodiments, the combination of the separation distance 510 of the gap 315 (FIG. 5) and the remaining amount of the mold compound 410 in the gap 315 (FIG. 4) can be selected so as to promote separation of the mold compound 305 remaining in the gap 315 during the curing step 115. For instance, as a non-limiting example, in some embodiments when the separation distance 510 equals 1 mm and the mold compound 305 occupies about 10 percent of the gap 315, certain mold compounds 305 (e.g., epoxy molds) in the gap 315 may tear apart as the adjacent laterally separated mold sub-arrays 310 are cured as part of step 115. Selecting the separation distance 510 and the remaining amount of the mold compound 305 to promote such tearing in this fashion can help to mitigate lateral forces from being transferred from one mold sub-arrays 310 to adjacent mold sub-arrays 310. Based upon the present disclosure, one skilled in the pertinent art would appreciate that the particular separation distance 510 and mold compound 305 remaining gap 315 could be adjusted to promote such tearing for different types of mold compounds 305, mold sub-array 310 sizes, die sizes 215, curing conditions, substrate surfaces 210 and adhesives thereon, or other parameters familiar to one skilled in the pertinent art.

For some embodiments of the invention manifest as a method 100 or a package 200, the areas of the mold sub-arrays 315 and/or the gap separation distances 510 are adjusted to provide efficient use of the carrier substrate 205 surface 210 without wasting any of the carrier substrate 205. As a non-limiting example, consider a mold compound 305 and curing step 115 conditions for which it is know that the yield of final device packages per carrier substrate 205 (e.g., the percentage of functional device packages diced away from other device packages of the same substrate 205) is at least about 99.5 percent when the area of the mold compound 305 on the substrate surface 210 equals about 177 mm² or less (e.g., a diameter of about 200 mm for circularly shaped substrate 205). To use such a mold compound and curing step 115 for a square carrier substrate 205 having a 1 meter² area and mold sub-arrays 310 spaced apart by a gap separation distance 510 of 1 mm, there can be 6 by 6 mold sub-arrays 315 on the substrate 205, each mold sub-array 315 being 165 mm² to thereby provide a total of 36 mold sub-arrays 315 per substrate 205. Or, in a similar embodiment, but using a gap separation distance 510 of 10 mm, there can be 6 by 6 mold sub-arrays 315 each being 160 mm² in area.

One of ordinary skill would understand that the embodiments method 100 can further include one or more of additional steps to complete the manufacture of the package 200 or intermediate packages 200.

FIG. 6 presents a cross-sectional view of embodiment of the invention manifest as another device package 200 analogous to the view depicted in FIG. 5, after further stages in an embodiment of the method 100 discussed in the context of FIG. 1. As illustrated in FIG. 6 in some embodiments of the invention manifest as a method 100, the carrier substrate 205 and dies 212, 215 can been inverted as compared to the orientation depicted in FIGS. 2A-5, to facilitate performing subsequent processing steps.

Some embodiments of the invention manifest as a method 100 can include a step 135 of removing the carrier substrate 205 to thereby expose the active sides 217 of the semiconductor device dies 215. As illustrated in FIG. 6, some embodiments the active sides 217 are substantially coplanar with a now-exposed side 605 of the mold sub-arrays 315 that the dies 215 are embedded in. The term substantially coplanar, as used herein, means that a difference in height 607 of the active side 217 either above or below the surface 608 of the side 605 of the mold sub-arrays 315 is about 1000 microns or less and in some embodiments about 100 microns or less and in some embodiments about 10 microns or less.

Some embodiments of the invention manifest as a method 100 include a step 140 of forming a dielectric layer 610 on the active sides 217 of the semiconductor device dies 215 and on the side 605 of the mold sub-arrays 310. One skilled in the pertinent arts would be familiar with various processes to form the dielectric layer 610. For example, the dielectric layer 610 can be formed by spin coating a polyimide or similar insulation electrically insulating material so as to be deposited over the active sides 217 and the side 605.

Some embodiments of the invention manifest as a method 100 or a package 200, include a step 145 of forming openings 615 in the dielectric layer 610 to expose contact pads 620 on the active side 217 of the dies 215. One skilled in the pertinent arts would be familiar with lithographic and etching processes to form the openings 615.

Some embodiments of the invention manifest as a method 100 include a step 150 of forming a metal layer 625 on the dielectric layer 610 and in the openings 615 of the dielectric layer 625. One skilled in the pertinent arts would be familiar with processes to form the metal layer 625. For example, in some embodiments a copper metal layer 625 can be deposited by an electroplating process using a copper plating solution (e.g., Roma Hass RHEM UltraFill 3000 Cu plating solution).

Some embodiments of the invention manifest as a method 100 include a step 155 of patterning the metal layer 625 to form an interconnect layer 630 that includes bond pads 635 on an outer surface 637 of the dielectric layer 610. In some embodiments interconnect layer 630 can interconnect dies 212, 215 that are the embedded within the same mold sub-array 310 (FIG. 3A). One skilled in the pertinent arts would be familiar with photolithographic processes to pattern the metal layer 625.

One skilled in the art would appreciate how the steps 140-155 could be repeated multiple times to form a patterned interconnection multilayer over the dies 212, 215 and the side 605 of the mold sub-arrays 310.

Some embodiments of the invention manifest as a method 100 include a step 160 of coupling solder balls 640 to the bond pads 635 to form a ball grid array 645. As illustrated in FIG. 6, in some embodiments, the ball grid array 645 can fan out beyond perimeters of the dies 212, 215.

Some embodiments of the invention manifest as a method 100 includes a step 165 of dicing the mold sub-arrays 310 to form individual device packages 200 such as flip-chip packages.

For example in some embodiments the dicing step 165 includes removing a region 650 that includes remaining portions of the grid frame 240, portions of adjacent mold sub-arrays 310 and portions of the dielectric layer 610 located on the adjacent mold sub-arrays 310 in the vicinity of the gap 315 separating the adjacent mold sub-arrays 310.

Another embodiment of the invention manifest as an integrated circuit package, such as any of the packages 200 depicted in FIGS. 3A-6 and which in some embodiments can be formed using one or more aspects of the method embodiments described in the context of FIG. 1.

In some embodiments the IC package 200 can be provided at an intermediate stage of manufacturing such as depicted in any of FIGS. 2A-5, e.g., for subsequent processing by an end-user. For instance, in some embodiments, the dies 212, 215 of the IC packages 200 embedded within the same mold sub-array (FIG. 3A) can be interconnected each other or to the ball grid array 645 in different fashions to provide different types individualized packages 200 according to the specific needs of different end-users after the dicing step 165.

The package 200 comprises a plurality of semiconductor device dies 212, 215 embedded in one of a plurality of laterally spaced-apart mold sub-arrays 310 (FIG. 3A). The active side 217 of the dies 212, 215 are not covered by the spaced-apart mold sub-arrays 310 and the active side 217 is substantially in a same plane as one side 605 of the spaced-apart mold sub-arrays 310.

In some embodiments of the invention manifest as an IC package 200, the semiconductor device dies 212, 215 are grouped into regions 230 on the planar surface 210 (FIG. 2A). The regions 230 can be separated by die-free zones 235 situated so as to correspond to gaps 315 between the laterally spaced-apart mold sub-arrays 310.

In some embodiments of the invention manifest as an IC package 200, adjacent ones of the mold sub-arrays 310 can have a separation distance 510 (FIG. 5) that is a value in a range from about 2 microns to about 100 mm. In some embodiments the separation distance 510 can be in a range of about 2 microns to about 100 microns or in some embodiments, the range of about 2 to about 10 microns. In some embodiments, the separation distance 510 can be in a range of about 100 microns to about 10000 microns and in some embodiments, a range of about 100 to about 1000 microns. In some embodiments, the separation distance 510 can be in a range of about 10 mm to about 100 mm.

In some embodiments of the invention manifest as an IC package 200, the gap 315 between the laterally spaced-apart mold sub-arrays 310 is free of mold compound. In some embodiments, the gap 315 includes up to about 50 percent of the mold compound 305, and in some embodiments, up to 25 percent, and in some embodiments up to 10 percent of the mold compound 305. In some embodiments, the gap 315 is an open space, e.g., an air-filled gap. In some embodiments the gap 315 is occupied with a portion of the grid frame 240, such as a portion of a grid frame wall 245.

In some embodiments of the invention manifest as an IC package 200, the dies 212, 215 are surrounded by a film 222 on at least sidewalls 225 of the dies 212, 215. In some embodiments, the film 222 conformally covers both the side walls 225 and bottoms 227 of the dies 212, 215.

In some embodiments of the invention manifest as an IC package 200, the package 200 further includes a dielectric layer 610 located on the active side 217 of the dies 212, 215 and on the one side 605 of the mold compound 305.

In some embodiments of the invention manifest as an IC package 200, the package 200 further includes metal interconnections 630 located on the dielectric layer 610 and in openings 615 in the dielectric layer 610. In some embodiments, the metal interconnections 630 can contact the contact pads 620 on the dies 212, 215 and can include bond pads 635 and on an outer surface 637 of the dielectric layer 610.

In some embodiments of the invention manifest as an IC package 200, the package 200 further includes a ball grid array 645 of solder balls 640 coupled to the bond pads 635 of the metal interconnections 630.

Although embodiments of the invention have been described herein with reference to the accompanying drawings, it is to be understood that embodiments of the invention are not limited to the described embodiments. Those skilled in the art to which this application relates will contemplate various other embodiments of the invention within the scope of the following claims.

1. A method of manufacturing an integrated circuit package, comprising:
providing a carrier substrate having a planar surface;
forming a grid frame on the planar surface of the carrier substrate, the grid frame having a plurality of openings therein;
placing a plurality of semiconductor device dies active-side down at laterally spaced-apart locations as defined by locations of the grid frame openings on the planar surface;
covering the semiconductor device dies with a mold compound to form laterally spaced-apart mold sub-arrays on the planar surface; and
curing the laterally spaced-apart mold sub-arrays, wherein the semiconductor device dies are retained at substantially the same laterally spaced-apart locations on the planar surface after the curing, and adjacent ones of the mold sub-arrays are each separated by a gap having a separation distance that is a value in a range from about 2 microns to about 10 microns and wherein the gap is occupied by a portion of the grid frame.

2. The method of claim 1, further including forming a film around at least sidewalls of the dies before covering the semiconductor device dies with the mold compound.

3. The method of claim 1, wherein the semiconductor device dies are grouped into regions on the planar surface, wherein the regions are separated by die-free zones situated so as to correspond to locations of the gaps between the laterally spaced-apart mold sub-arrays.

4. A method of manufacturing an integrated circuit package, comprising:
providing a carrier substrate having a planar surface;
placing groups of semiconductor device dies active-side down on the planar surface, wherein each one of the groups of semiconductor device dies form discrete regions that are separated from each other by gaps that are die-free and frame-free zones;
depositing discrete portions of a mold compound to separately cover each of the groups of the semiconductor device dies to define laterally spaced-apart mold sub-arrays on the planar surface; and
curing the laterally spaced-apart mold sub-arrays, wherein the semiconductor device dies are retained at substantially the same laterally spaced-apart locations on the planar surface after the curing.

5. (canceled)

6. The method of claim 1, wherein forming the grid frame includes coupling a preformed grid frame to the planar surface.

7. The method of claim 5, wherein forming the grid frame include depositing a elastomeric layer on the planar surface and patterning the elastomeric layer to form the grid frame.

8. The method of claim 5, further including removing the grid frame after the curing of the laterally spaced-apart mold sub-arrays.

9. The method of claim 5, wherein the grid frame is retained after the curing of the laterally spaced-apart mold sub-arrays.

10. The method of claim 5, wherein the grid frame is composed of an elastomeric material.

11. The method of claim 4, wherein adjacent ones of the mold sub-arrays have a separation distance that is a value in a range from about 10 mm to about 100 mm.

12. The method of claim 4, wherein the gaps between adjacent ones of the mold sub-arrays are free of the mold compound.

13. The method of claim 4, wherein the gaps between adjacent ones of the mold sub-arrays are filled with up to about 50 percent of the mold compound.

14. The method of claim 4, wherein the gaps between adjacent ones of the mold sub-arrays are filled with up to about 10 percent of the mold compound.

15. The method of claim 1, wherein individual ones of the mold sub-arrays are configured to occupy an area on the planar surface of less than about 177 mm².

16. The method of claim 1, further including, after the curing one or more of:
removing the carrier substrate to thereby expose the active sides of the semiconductor device dies wherein the exposed active sides are substantially coplanar with one side of the mold sub-arrays that the semiconductor device dies are embedded in;
forming a dielectric layer on the active side of the semiconductor device dies and on the one side of the mold sub-arrays;
forming openings in the dielectric layer to expose contact pads on the active sides;
forming a metal layer on the dielectric layer and in the openings;
patterning the metal layer to form an interconnect layer that includes bond pads;
coupling solder balls to the bond pads to form a ball grid array; and
dicing the mold sub-arrays.

17. An integrated circuit package, comprising:
a plurality of semiconductor device dies embedded in one of a plurality of laterally spaced-apart mold sub-arrays, wherein an active side of the dies are not covered by the spaced-apart mold sub-arrays and the active side of the dies are substantially in a same plane as one side of the spaced-apart mold sub-arrays.

18. The package of claim 17, wherein the semiconductor device dies are grouped into regions on the planar surface, wherein the regions are separated by die-free zones situated so as to correspond to gaps between the laterally spaced-apart mold sub-arrays.

19. The package of claim 17, wherein adjacent ones of the mold sub-arrays have a separation distance that is a value in a range from about 2 microns to about 100 mm

20. The package of claim 17, further including:
a dielectric layer located on the active side of the dies and on the one side of the mold compound;
metal interconnections located on the dielectric layer and in openings in the dielectric layer, the metal interconnection contacting contact pads on the dies and including bond pads on an outer surface of the dielectric layer; and
ball grid array of solder balls coupled to the bond pads of the metal interconnection.
